(19) United States
(12) Patent Application Publication
(10) Pub. No.: US 2025/0095961 A1
(43) Pub. Date: Mar. 20, 2025

(54) INDUCTIVELY COUPLED PLASMA DEVICE FOR EXHAUST GAS TREATMENT

(71) Applicant: LOT CES CO., LTD., Osan-si, Gyeonggi-do (KR)

(72) Inventors: Jin Ho BAE, Hwaseong-si Gyeonggi-do (KR); Jeong Kyun RA, Hwaseong-si, Gyeonggi-do (KR); Min Jae KIM, Ansan-si, Gyeonggi-do (KR)

(73) Assignee: LOT CES CO., LTD., Osan-si, Gyeonggi-do (KR)

(21) Appl. No.: 18/293,328

(22) PCT Filed: Apr. 25, 2023
(86) PCT No.: PCT/KR2023/005586

§ 371 Date: Jan. 29, 2024

(30) Foreign Application Priority Data
Apr. 29, 2022 (KR) 10-2022-0053176

(51) Int. Cl. H01J 37/32

(52) U.S. Cl. CPC H01J 37/3211; H01J 37/32183; H01J 37/32844

(57) ABSTRACT

Provided is an inductively coupled plasma device for treating an exhaust gas, the inductively coupled plasma device including: an inductively coupled plasma reactor installed on an exhaust pipe through which exhaust gas generated from a process chamber of a semiconductor manufacturing facility is discharged, the inductively coupled plasma reactor configured to generate inductively coupled plasma and treat the exhaust gas per repeated operation cycle; an electric power supply configured to supply radio frequency power to the inductively coupled plasma reactor through a transmission line; and an impedance matching unit configured to match impedance at a side of the inductively coupled plasma reactor and impedance at a side of the electric power supply to each other.

### TECHNICAL FIELD

The present invention relates to technology for treating an exhaust gas discharged from a process chamber of a semiconductor manufacturing facility by using plasma, and more particularly, to technology for treating an exhaust gas discharged from a process chamber of a semiconductor manufacturing facility by using inductively coupled plasma.

### BACKGROUND ART

Semiconductor devices are being manufactured when processes such as photolithography, etching, diffusion and metal deposition and the like are repeatedly performed on a wafer in a process chamber. Among these semiconductor manufacturing processes, various process gases are used, and a residual gas in the process chamber after the processes are performed, includes various harmful components, such as perfluorinated chemicals (PFCs) and the like. The residual gas in the process chamber is discharged by a vacuum pump through an exhaust line after the processes are completed, and an exhaust gas is purified by an exhaust gas treatment device so that the harmful components are not discharged as they are.

Recently, technology for decomposing and treating harmful components by using a plasma reaction is being widely used. Korean Patent Laid-open Publication No. 2019-19651 discloses a plasma chamber for treating an exhaust gas by using inductively coupled plasma. When radio frequency power is applied to an antenna coil, a magnetic field is induced by a time-varying current flowing through the antenna coil, and inductively coupled plasma is generated by an electric field generated inside the chamber. In general, an inductively coupled plasma reactor includes a chamber for providing a space in which plasma is generated, a ferrite core bonded to enclose the chamber, the antenna coil wound around the ferrite core, and an igniter for initial plasma ignition. The inductively coupled plasma reactor receives radio frequency power from an electric power supply, and for efficient supply of power, impedance between the inductively coupled plasma reactor and the electric power supply needs to be properly matched to each other. In the inductively coupled plasma reactor, the impedance varies according to a reactive environment, and when impedance at the side of the inductively coupled plasma reactor and impedance at the side of the electric power supply are not matched to each other, problems such as plasma off, reduction in the supply amount of power, damage of an electric power supply device, inefficient power use, a pressure increase of facility, and the like occur. Thus, impedance at the side of the inductively coupled plasma reactor and impedance at the side of the power supply are matched to each other by using impedance matching technology, and impedance matching according to the related art is a fully automatic or manual method, and a fully automatic method according to the related art is expensive, and the use of the manual method according to the related art is inconvenient, and thus improvements are required.

Korean Patent Registration No. 10-0457632 discloses an impedance automatic matching device for performing matching of impedances between a reaction chamber for processing a wafer by using plasma and a radio frequency power generator for plasma generation.

### DETAILED DESCRIPTION OF THE INVENTION

### Technical Problem

The present invention provides an inductively coupled plasma device for treating an exhaust gas in which an impedance change range is extended compared to the related art so that the efficiency of power settings in response to various operation conditions may be improved.

### Technical Solution

According to an aspect of the present invention, there is provided an inductively coupled plasma device for treating an exhaust gas, the inductively coupled plasma device including: an inductively coupled plasma reactor installed on an exhaust pipe through which exhaust gas generated from a process chamber of a semiconductor manufacturing facility is discharged, the inductively coupled plasma reactor configured to generate inductively coupled plasma and treat the exhaust gas per repeated operation cycle; an electric power supply configured to supply radio frequency power to the inductively coupled plasma reactor through a transmission line; and an impedance matching unit configured to match impedance at a side of the inductively coupled plasma reactor and impedance at a side of the electric power supply to each other, wherein the impedance matching unit includes a first impedance changing unit including a variable capacitor element, a second impedance changing unit including a transformer, an operation data meter configured to measure operation data of the inductively coupled plasma reactor, and a controller configured to adjust capacitance by the variable capacitor element by using an operation data sampling value obtained by the operation data meter in one operation cycle and to control whether or not the transformer operates, to change matching impedance.

### Effects of the Invention

According to the present invention, all of the objectives of the present invention described above can be achieved. Specifically, the change range of impedance is extended through the combination of a first impedance changing unit for changing capacitance and a second impedance changing unit as a transformer with the changed winding ratio, so that appropriate power settings in response to various operation conditions such as flow conditions and the like can be performed.

### BRIEF DESCRIPTION OF THE DRAWINGS

FIG. 1 illustrates a schematic configuration of a semiconductor manufacturing facility equipped with an inductively coupled plasma device for treating an exhaust gas according to an embodiment of the present invention;

FIG. 2 illustrates a schematic configuration of an inductively coupled plasma device for treating an exhaust gas, according to an embodiment of the present invention installed in the semiconductor manufacturing facility illustrated in FIG. 1;

FIG. 3 is a view schematically illustrating an embodiment of a second impedance changing unit of an impedance matching unit provided in the inductively coupled plasma device illustrated in FIG. 2;

FIG. 4 is a table showing an example of impedance changing by using the impedance matching unit provided in the inductively coupled plasma device illustrated in FIG. 2; and

FIG. 5 is a flowchart schematically illustrating an impedance matching method for the inductively coupled plasma device illustrated in FIG. 2, according to an embodiment of the present invention.

### MODE FOR CARRYING OUT THE INVENTION

Hereinafter, the configuration and operation of embodiments of the present invention will be described in detail with reference to the accompanying drawings.

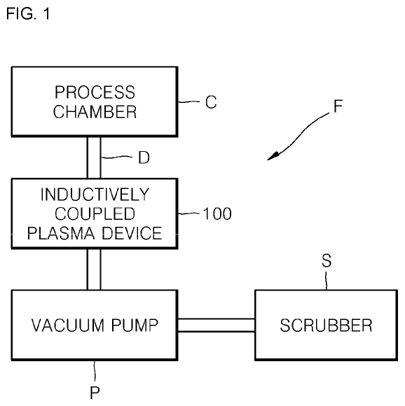

FIG. 1 is a block diagram illustrating the schematic configuration of a semiconductor manufacturing facility equipped with an inductively coupled plasma device for treating an exhaust gas according to an embodiment of the present invention. Referring to FIG. 1, a semiconductor manufacturing facility F includes a process chamber C in which a semiconductor manufacturing process is performed by using various process gases, an exhaust pipe D through which a residual gas generated in the process chamber C is discharged, a scrubber S for treating exhaust gas discharged through the exhaust pipe D from the process chamber C, a vacuum pump P in which a discharge pressure is formed on the exhaust pipe D so that the residual gas generated in the process chamber C is discharged through the exhaust pipe D, and an inductively coupled plasma device 100 according to an embodiment of the present invention, for treating an exhaust gas flowing along the exhaust pipe D at an upstream side of the vacuum pump P by using inductively coupled plasma. The feature of the present invention is that the process chamber C, the vacuum pump P, the scrubber S and the exhaust pipe D that are the remaining configurations other than the inductively coupled plasma device 100 in the semiconductor manufacturing facility illustrated in FIG. 1 as the inductively coupled plasma device 100 for treating the exhaust gas can be formed within the general technical range relating to the present invention.

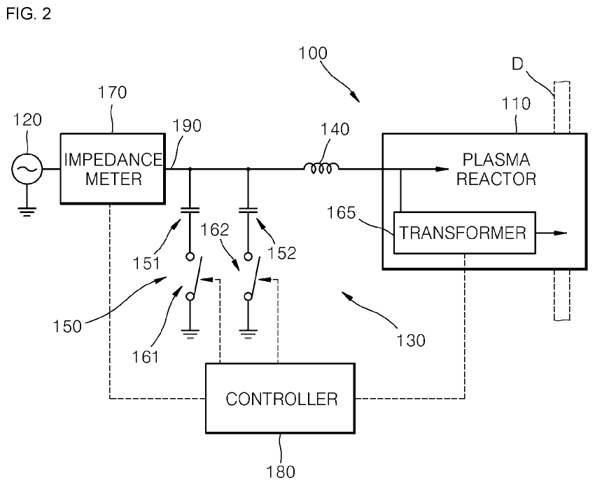

The inductively coupled plasma device 100 treats the exhaust gas flowing along the exhaust pipe D at the upstream side of the vacuum pump P by using inductively coupled plasma. FIG. 2 schematically illustrates the configuration of the inductively coupled plasma device 100. Referring to FIG. 2, the inductively coupled plasma device 100 includes an inductively coupled plasma reactor 110 installed on the exhaust pipe D, an electric power supply 120 for supplying radio frequency power to the inductively coupled plasma reactor 110, and an impedance matching unit 130 for matching impedances between the inductively coupled plasma reactor 110 and the electric power supply 120 to each other.

The inductively coupled plasma reactor 110 is installed on the exhaust pipe D and treats the exhaust gas flowing along the exhaust pipe D by using inductively coupled plasma. Since the inductively coupled plasma reactor 110 includes that of a configuration generally used in the art (e.g., Korean Patent Registration No. 10-2155631), detailed descriptions thereof will be omitted. The inductively coupled plasma reactor 110 generates plasma for treating the exhaust gas by using radio frequency power supplied from the electric power supply 120 through a radio frequency transmission line 190. In the present embodiment, it is described that the inductively coupled plasma reactor 110 is located at an upstream than the vacuum pump P on the exhaust pipe D, but unlike this, the inductively coupled plasma reactor 110 may be located at a downstream than the vacuum pump P, and this also belongs to the scope of the present invention.

The electric power supply 120 supplies radio frequency power to the inductively coupled plasma reactor 110 through the radio frequency transmission line 190 so that inductively coupled plasma can be generated in the inductively coupled plasma reactor 110.

The impedance matching unit 130 is installed on the radio frequency transmission line 190 and matches impedance at the side of the inductively coupled plasma reactor 110 and impedance at the side of the electric power supply 120 to each other so that radio frequency power can be efficiently transmitted to the inductively coupled plasma reactor 110 from the electric power supply 120. The impedance matching unit 130 matches impedance at the side of the plasma reactor 110 and the impedance at the side of the electric power supply 120 to each other by changing its impedance in response to reflected power output from the inductively coupled plasma reactor 110. The impedance matching unit 130 includes an inductor 140 serially connected to the radio frequency transmission line 190, a first impedance changing unit 150 electrically connected to the radio frequency transmission line 190 to change the impedance, a second impedance changing unit 165 electrically connected to the radio frequency transmission line 190 to change the impedance, an impedance meter for measuring impedance by detecting a voltage and a current of the reflected power transmitted from the inductively coupled plasma reactor 110 to the electric power supply 120, and a controller 180 for controlling operations of the first impedance changing unit 150 and the second impedance changing unit 165 by using impedance data measured by the impedance meter 170.

The inductor 140 is serially connected to the radio frequency transmission line 190 and provides an inductance fixed in the impedance matching unit 130.

The first impedance changing unit 150 is electrically connected to the radio frequency transmission line 190 to change the impedance. The first impedance changing unit 150 includes a plurality of capacitors 151 and 152 connected in parallel to the radio frequency transmission line 190, and a plurality of switches 161 and 162 that regulate electrical connection between the plurality of capacitors 151 and 152 and the radio frequency transmission line 190.

The plurality of capacitors 151 and 152 are sequentially connected to the radio frequency transmission line 190, and each of the plurality of capacitors 151 and 152 is connected in parallel to the radio frequency transmission line 190. In the present embodiment, it is described that the capacitors 151 and 152 are two, and the present invention is not limited thereto, and one or three or more capacitors may be present, and this also belongs to the scope of the present invention. In the present embodiment, one capacitor 151 of two capacitors 151 and 152 is referred to as a first capacitor, and the other one capacitor 152 is referred to as a second capacitor. The first capacitor 151 provides a fixed first capacitance C1, and the second capacitor 152 provides a fixed second capacitance C2. The first capacitance C1 and the second capacitance C2 have different values, and in the present embodiment, it is described that the second capacitance C2 is greater than the first capacitance C1. The plurality of capacitors 151 and 152 constitute a variable 20) capacitor element.

In the present embodiment, it is described that the first capacitor 151 includes one capacitor having the first capacitance C1, but the present invention is not limited thereto. The first capacitor 151 may be constituted by connecting a plurality of capacitors in series, in parallel or in a series/parallel mixed manner to have the first capacitance C1, and this also belongs to the scope of the present invention.

In the present embodiment, it is described that the second capacitor 152 includes one capacitor having the second capacitance C2, but the present invention is not limited thereto. The second capacitor 152 may be constituted by connecting a plurality of capacitors in series, in parallel or in a series/parallel mixed manner to have the second capacitance C2, and this also belongs to the scope of the present invention.

Each of the plurality of switches 161 and 162 is installed to correspond to each of the plurality of capacitors 151 and 152 one-to-one and regulates electrical connection between each of the plurality of capacitors 151 and 152 and the radio frequency transmission line 190. In the present embodiment, it is described that the number of the switches 161 and 162 is two corresponding to the number of the capacitors 151 and 152, and the number of the switches 161 and 162 may be changed to correspond to the number of the capacitors 151 and 152. In the present embodiment, the switch 161 of two switches 161 and 162 corresponding to the first capacitor 151 is referred to as a first switch, and the switch 162 of two switches 161 and 162 corresponding to the second capacitor 152 is referred to as a second switch. That is, the first switch 161 regulates electrical connection between the first capacitor 151 and the radio frequency transmission line 190, and the second switch 162 regulates electrical connection between the second capacitor 152 and the radio frequency transmission line 190. The on·off operation of the first switch 161 and the second switch 162 is independently controlled by the controller 180. The first impedance changing unit 150 may change the impedance into four cases according to the on off state of each of the first switch 161 and the second switch 162. One of four cases is the case where all of two switches 161 and 162 are in off states and thus all of two capacitors 151 and 152 do not affect total impedance value, and another case is the case where only the first switch 161 of two switches 161 and 162 is in an on state and thus only the first capacitor 151 of two capacitors 151 and 152 affects total impedance value, and another case is the case where only the second switch 162 of two switches 161 and 162 is in an on state and thus only the second capacitor 152 of two capacitors 151 and 152 affects total impedance value, and the other one case is the case where all of two switches 161 and 162 are in on states and thus all of two capacitors 151 and 152 affect total impedance value.

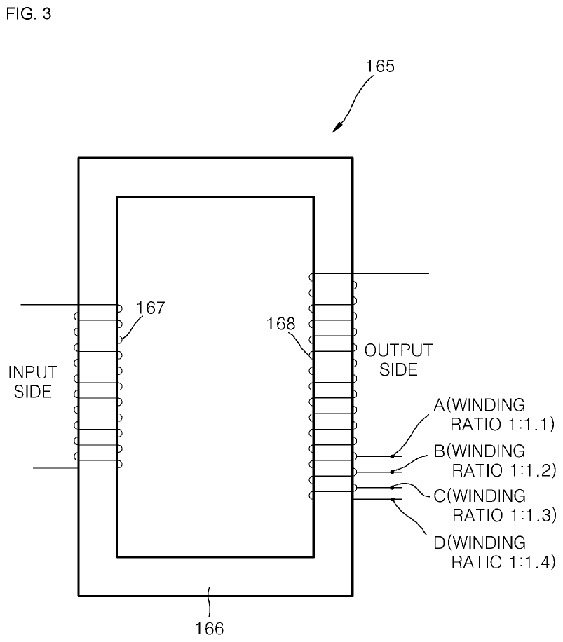

The second impedance changing unit 165 is electrically connected to the radio frequency transmission line 190 and changes the impedance. FIG. 2 illustrates that the second impedance changing unit 165 is installed in the inductively coupled plasma reactor 110, but unlike this, may be installed outside the inductively coupled plasma reactor 110, and this also belongs to the scope of the present invention. The second impedance changing unit 165 may be selectively electrically connected in series to the radio frequency transmission line 190. That is, the second impedance changing unit 165 is electrically connected in series to the radio frequency transmission line 190 or electrical connection between the second impedance changing unit 165 and the radio frequency transmission line 190 is interrupted. FIG. 3 schematically illustrates the configuration of the second impedance changing unit 165. Referring to FIGS. 2 and 3, the second impedance changing unit 165 is a transformer, and includes an iron core 166, a primary coil 167 formed in the iron core 166, and a secondary coil 168 formed in the iron core 166.

Since the iron core 166 includes the configuration commonly used in the transformer, detailed descriptions thereof are omitted. The primary coil 167 and the secondary coil 168 are formed in the iron core 166.

The primary coil 167 is formed by winding a conductive line around the iron core 166, is electrically connected to the electric power supply 120 and constitutes an input side of the transformer.

The secondary coil 168 is formed by winding a conductive line around the iron core 166, is electrically connected to a plasma generator of the inductively coupled plasma reactor 110 and constitutes an output side of the transformer. The winding ratio of the transformer is selected by the controller 180 in the secondary coil 168 and may be output. In the present embodiment, it is described that one of four points A, B, C and D of the secondary coil 168 is selected and thus one of four winding ratios (the number of winding ratios of the secondary coil 168 with respect to the number of winding ratios of the primary coil 167), and the present invention is not limited thereto. In the present embodiment, it is described that point A provides the winding ratio of 1:1.1, point B provides the winding ratio of 1:1.2, point C provides the winding ratio of 1:1.3, and point D provides the winding ratio of 1:1.4. The impedance is variously changed according to the winding ratio selected by the second impedance changing unit 165 that is a transformer.

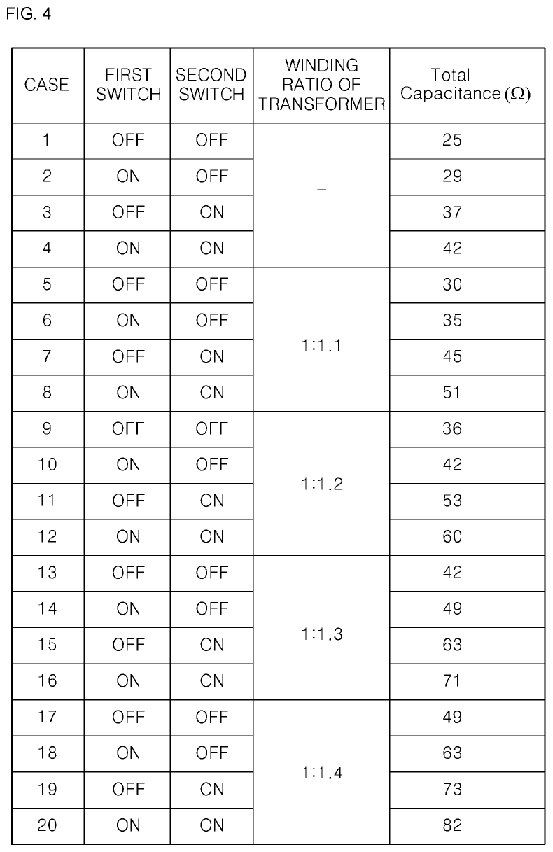

The impedance change range provided by the impedance matching unit 130 may be widely extended through the combination of the first impedance changing unit 150 and the second impedance changing unit 165. FIG. 4 is a table showing an example of impedance changing by using the impedance matching unit 130 provided in the inductively coupled plasma device illustrated in FIG. 2. Referring to the table of FIG. 4, the impedance matching unit 130 provides 20 impedance values for impedance matching.

In the table of FIG. 4, CASE 1-4 is the case where the second impedance changing unit 165 is not used but only the first impedance changing unit 150 is used. CASE 1 is the case where all of the first switch 161 and the second switch 162 of the first impedance changing unit 150 are in off states, and provides an impedance value of 259. CASE 2 is the case where the first switch 161 of the first impedance changing unit 150 is in an on state and the second switch 162 is in an off state, and provides an impedance value of 299. CASE 3 is the case where all of the first switch 161 of the first impedance changing unit 150 are in an off state and the second switch 162 is in an on state, and provides an impedance value of 379. CASE 4 is the case where all of the first switch 161 and the second switch 162 of the first impedance changing unit 150 are in on states, and provides an impedance value of 429.

In the table of FIG. 4, CASE 5-8 is the case where the second impedance changing unit 165 operating with the winding ratio of 1:1.1 with respect to the first impedance changing unit 150 is used. CASE 5 is the case where all of the first switch 161 and the second switch 162 of the first impedance changing unit 150 are in off states, and provides an impedance value of 309. CASE 6 is the case where the first switch 161 of the first impedance changing unit 150 is in an on state and the second switch 162 is in an off state, and provides an impedance value of 359. CASE 7 is the case where the first switch 161 of the first impedance changing unit 150 is in an off state and the second switch 162 is in an on state, and provides an impedance value of 459. CASE 8 is the case where all of the first switch 161 and the second switch 162 of the first impedance changing unit 150 are in on states, and provides an impedance value of 519.

In the table of FIG. 4, CASE 9-12 is the case where the second impedance changing unit 165 operating with the winding ratio of 1:1.2 with respect to the first impedance changing unit 150 is used. CASE 9 is the case where all of the first switch 161 and the second switch 162 of the first impedance changing unit 150 are in off states, and provides an impedance value of 369. CASE 10 is the case where the first switch 161 of the first impedance changing unit 150 is in an on state and the second switch 162 is in an off state, and provides an impedance value of 429. CASE 11 is the case where the first switch 161 of the first impedance changing unit 150 is in an off state and the second switch 162 is in an on state, and provides an impedance value of 539. CASE 12 is the case where all of the first switch 161 and the second switch 162 of the first impedance changing unit 150 are in on states, and provides an impedance value of 609.

In the table of FIG. 4, CASE 13-16 is the case where the second impedance changing unit 165 operating with the winding ratio of 1:1.3 with respect to the first impedance changing unit 150 is used. CASE 13 is the case where all of the first switch 161 and the second switch 162 of the first impedance changing unit 150 are in off states, and provides an impedance value of 429. CASE 14 is the case where the first switch 161 of the first impedance changing unit 150 is in an on state and the second switch 162 is in an off state, and provides an impedance value of 499. CASE 15 is the case where the first switch 161 of the first impedance changing unit 150 is in an off state and the second switch 162 is in an on state, and provides an impedance value of 639. CASE 16 is the case where all of the first switch 161 and the second switch 162 of the first impedance changing unit 150 are in on states, and provides an impedance value of 710.

In the table of FIG. 4, CASE 17-20 is the case where the second impedance changing unit 165 operating with the winding ratio of 1:1.4 with respect to the first impedance changing unit 150 is used. CASE 17 is the case where all of the first switch 161 and the second switch 162 of the first impedance changing unit 150 are in off states, and provides an impedance value of 499. CASE 18 is the case where the first switch 161 of the first impedance changing unit 150 is in an on state and the second switch 162 is in an off state, and provides an impedance value of 639. CASE 19 is the case where the first switch 161 of the first impedance changing unit 150 is in an off state and the second switch 162 is in an on state, and provides an impedance value of 739. CASE 20 is the case where all of the first switch 161 and the second switch 162 of the first impedance changing unit 150 are in on states, and provides an impedance value of 829.

Impedance data according to the switch on·off state illustrated in FIG. 4, whether or not the transformer is used, and the selection of the winding ratio of the transformer are stored in the controller 180, and is utilized in controlling of the first impedance changing unit 150 and the second impedance changing unit 165.

The impedance meter 170 detects the voltage/current of reflected power transmitted from the inductively coupled plasma reactor 110 to the electric power supply 120 to measure impedance. Since impedance measurement and matching through voltage/current detection includes the configuration commonly used, detailed descriptions thereof are omitted.

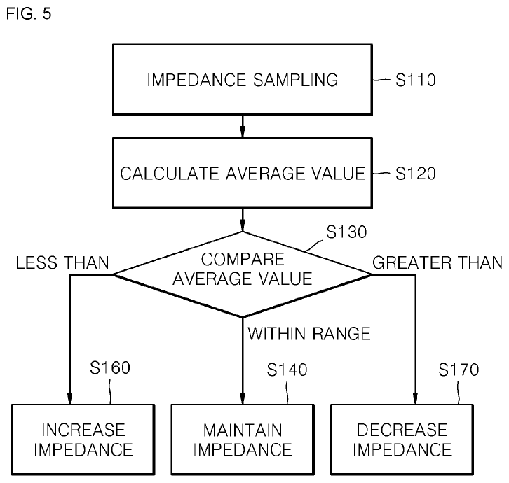

The controller 180 controls the operations of the first switch 161 and the second switch 162, whether or not the second impedance changing unit 165 is used, and selection of the winding ratio of the second impedance changing unit 165 independently by using the impedance value measured by the impedance meter 170. The controller 180 may include a computer program for performing an impedance matching method in hardware, table data illustrated in FIG. 4, a memory device in which appropriate range data of impedance generated by the plasma reactor 110 is stored, and a central processing unit (CPU) for executing a computer program for performing an impedance matching method stored in the memory device. The impedance matching method according to an embodiment of the present invention is performed by the controller 180, and a detailed operation of the controller 180 will be described in detail by the impedance matching method illustrated in FIG. 5.

FIG. 5 is a flowchart schematically illustrating an impedance matching method for the inductively coupled plasma device illustrated in FIG. 2, according to an embodiment of the present invention. Referring to FIG. 2 together with FIG. 5, the impedance matching method for the inductively coupled plasma device according to an embodiment of the present invention includes an impedance sampling operation (S110) in which impedance output from the inductively coupled plasma reactor 110 is sampled a plurality of times and is acquired as a plurality of impedance sampling values, an average value calculating operation (S120) in which an impedance sampling average value as an average value of the plurality of impedance sampling values acquired in the impedance sampling operation (S110) is calculated, an average value comparing operation (S130) in which the impedance sampling average value calculated in the average value calculating operation (S120) is compared with a preset allowable impedance, an impedance maintaining operation (S140) in which the impedance of the impedance matching unit 130 is maintained without changes according to the comparison result in the average value comparing operation (S130), an impedance increasing operation (S160) in which the impedance of the impedance matching unit 130 is increased according to the comparison result in the average value comparing operation (S130), and an impedance decreasing operation (S170) in which the impedance of the impedance matching unit 130 is decreased according to the comparison result in the average value comparing operation (S130). Respective operations of the method illustrated in FIG. 5 are performed per operation cycle of the inductively coupled plasma reactor 110.

In the impedance sampling operation (S110), reflected power output from the inductively coupled plasma reactor 110 is sampled a plurality of times so that a plurality of impedance sampling values are acquired. The impedance sampling operation (S110) is performed in such a way that, in one cycle operation section of the inductively coupled plasma reactor 110, after a predetermined amount of time has elapsed after the operation of the inductively coupled plasma reactor 110 starts, the impedance meter 170 samples the impedance from the inductively coupled plasma 120 a plurality of times according to a reflected power measurement command transmitted from the controller 180 to the impedance meter 170 and the controller 180 acquires a plurality of impedance sampling values sampled by the impedance meter 170.

In the average value calculating operation (S120), an impedance sampling average value of the plurality of impedance sampling values acquired in the impedance sampling operation (S110) is calculated by the controller 180.

In the average value comparing operation (S130), the impedance sampling average value calculated in the average value calculating operation (S120) is compared with a range (an allowable impedance minimum value RP_min to an allowable impedance maximum value RP_max) of a preset allowable impedance.

In the average value comparing operation (S130), when it is confirmed that the impedance sampling average value is within the range of the preset allowable impedance, the impedance maintaining operation (S140) is performed, and when it is checked that the impedance sampling average value is less than the allowable impedance minimum value RP_min, the impedance increasing operation (S160) is performed, and when it is checked that the impedance sampling average value is greater than the allowable impedance maximum value RP_max, the impedance decreasing operation (S170) is performed.

In the impedance maintaining operation (S140), the impedance of the impedance matching unit 130 is maintained without changes. The impedance maintaining operation (S140) is performed in such a way that the controller 180 outputs a control signal for maintaining the operating states of the first impedance changing unit 150 and the second impedance changing unit 165 without changes to the first impedance changing unit 150 and the second impedance changing unit 165. The impedance (matching impedance) of the impedance matching unit 130 maintained in the impedance maintaining operation (S140) persists until one cycle operation of the inductively coupled plasma reactor 110 ends and the average value comparing operation (130) is performed in the next cycle.

In the impedance increasing operation (S160), the impedance of the impedance matching unit 130 is increased. The impedance increasing operation (S160) is performed in such a way that the controller 180 changes the operating states of the first impedance changing unit 150 and the second impedance changing unit 165 so that the impedance (matching impedance) of the impedance matching unit 130 is increased compared to an initially-set impedance based on the table illustrated in FIG. 4. The operating state of the first impedance changing unit 150 is changed according to the on·off of two switches 161 and 162, and the operating state of the second impedance changing unit 165 is changed according to whether or not the second impedance changing unit 165 and the radio frequency transmission line 190 are connected to each other, and the selected winding ratio. In the impedance increasing operation (S160), an increase in the impedance of the impedance matching unit 130 is performed in proportion to the size of a value in which the impedance sampling average value is less than the allowable impedance minimum value RP_min. That is, the greater the size of the value in which the impedance sampling average value is less than the allowable impedance minimum value RP_min, an impedance increase value of the impedance matching unit 130 may be increased. The impedance of the impedance matching unit 130 increased once in the impedance increasing operation (S160) is maintained until one cycle operation of the inductively coupled plasma reactor 110 ends and the average value comparing operation (S130) is performed in the next cycle.

In the impedance decreasing operation (S170), the impedance of the impedance matching unit 130 is decreased. The impedance decreasing operation (S170) is performed in such a way that the controller 180 changes the operating states of the first impedance changing unit 150 and the second impedance changing unit 165 so that the impedance (matching impedance) of the impedance matching unit 130 is decreased compared to an initially-set impedance based on the table illustrated in FIG. 4. The operating state of the first impedance changing unit 150 is changed according to the on·off of two switches 161 and 162, and the operating state of the second impedance changing unit 165 is changed according to whether or not the second impedance changing unit 165 and the radio frequency transmission line 190 are connected to each other, and the selected winding ratio. In the impedance decreasing operation (S170), a decrease in the impedance of the impedance matching unit 130 is performed in proportion to the size of a value in which the impedance sampling average value is greater than the allowable impedance maximum value RP_max. That is, the greater the size of the value in which the impedance sampling average value is greater than the allowable impedance maximum value RP_max, an impedance decrease value of the impedance matching unit 130 may be increased. The impedance of the impedance matching unit 130 decreased once in the impedance decreasing operation (S170) is maintained until one cycle operation of the inductively coupled plasma reactor 110 ends and the average value comparing operation (130) is performed in the next cycle.

In the above-described embodiment, it is described that the controller 180 performs impedance matching by using voltage/current generated from the inductively coupled plasma reactor 110 measured by the impedance meter 170, but the present invention is not limited to using impedance for impedance matching. The impedance measured by the impedance meter 170 is an example of operation data relating to the inductively coupled plasma reactor 110 measured to perform impedance matching according to the present invention.

In the present embodiment, it is described that the second impedance changing unit 165 that is a transformer provides the winding ratio of 1:1.1 to 1:1.4 to change the impedance in the extended range of 259 to 829, but unlike this, the impedance may be changed in the further extended range of 109 to 1009 by providing the winding ratio of 1:0.5 to 1:2, for example, and this also belongs to the scope of the present invention.

According to the present invention, the change range of impedance can be extended through the combination of the first impedance changing unit 150 for changing capacitance and the second impedance changing unit 165 as a transformer for changing the winding ratio so that appropriate power settings in response to various operation conditions such as flow conditions and the like can be performed.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An inductively coupled plasma device for treating an exhaust gas, the inductively coupled plasma device comprising:
an inductively coupled plasma reactor installed on an exhaust pipe through which exhaust gas generated from a process chamber of a semiconductor manufacturing facility is discharged, the inductively coupled plasma reactor configured to generate inductively coupled plasma and treat the exhaust gas per repeated operation cycle;
an electric power supply configured to supply radio frequency power to the inductively coupled plasma reactor through a transmission line; and
an impedance matching unit configured to match impedance at a side of the inductively coupled plasma reactor and impedance at a side of the electric power supply to each other,
wherein the impedance matching unit comprises a first impedance changing unit including a variable capacitor element, a second impedance changing unit including a transformer, an operation data meter configured to measure operation data of the inductively coupled plasma reactor, and a controller configured to adjust capacitance by the variable capacitor element by using an operation data sampling value obtained by the operation data meter in one operation cycle and to control whether or not the transformer operates, to change matching impedance.

2. The inductively coupled plasma device of claim 1, wherein a winding ratio of the transformer is adjusted by the controller.

3. The inductively coupled plasma device of claim 2, wherein one of a plurality of winding ratios at a coil of an output side of the transformer is selected by the controller.

4. The inductively coupled plasma device of claim 1, wherein the variable capacitor element comprises a plurality of capacitors sequentially connected in parallel to the transmission line, and a plurality of switches that are installed to correspond to each of the plurality of capacitors one-to-one and regulate electrical connection between each of the plurality of capacitors and the transmission line.

5. The inductively coupled plasma device of claim 1, wherein the impedance matching unit regulates the matching impedance so that reflected power generated from the inductively coupled plasma reactor is reduced.

6. The inductively coupled plasma device of claim 1, wherein the operation data meter is further configured to measure impedance through a voltage and a current of the reflected power transmitted to the electric power supply from the inductively coupled plasma reactor, and the operation data sampling value is an impedance sampling value.

7. The inductively coupled plasma device of claim 6, wherein the impedance sampling value is obtained by the operation data meter in plurality, and the controller is configured to adjust the matching impedance by using an impedance sampling average value as an average value of the plurality of impedance sampling values.

8. The inductively coupled plasma device of claim 7, wherein the controller is further configured to compare the impedance sampling average value with a range of a preset allowable impedance, and when the impedance sampling average value is within the range of the allowable impedance, the controller is further configured to maintain initial operating states of the first impedance changing unit and the second impedance changing unit, and when the impedance sampling average value is out of the range of the allowable impedance, the controller is further configured to change at least one initial operating state of the first impedance changing unit and the second impedance changing unit.

9. The inductively coupled plasma device of claim 8, wherein, when the impedance sampling average value is less than an allowable impedance minimum value, the controller is further configured to change at least one operating state of the first impedance changing unit and the second impedance changing unit so that the matching impedance is increased.

10. The inductively coupled plasma device of claim 8, wherein, when the impedance sampling average value is greater than an allowable impedance maximum value, the controller is further configured to change at least one operating state of the first impedance changing unit and the second impedance changing unit so that the matching impedance is decreased.
